(19) United States
(12) Patent Application Publication
(10) Pub. No.: US 2024/0105832 A1
(43) Pub. Date: Mar. 28, 2024

(54) FIELD EFFECT TRANSISTOR COMPRISING EDGE TERMINATION AREA

(71) Applicant: Infineon Technologies AG, Neubiberg (DE)

(72) Inventors: Thomas Ralf SIEMIENIEC, Villach (AT); Hans-Joachim SCHULZE, Taufkirchen (DE); Jens Peter KONRATH, Villach (AT)

(21) Appl. No.: 18/371,620

(22) Filed: Sep. 22, 2023

(30) Foreign Application Priority Data
Sep. 22, 2022 (DE) 102022124385.0

(51) Int. Cl. H01L 29/78; H01L 21/04; H01L 29/16; H01L 29/66

(52) U.S. Cl. CPC H01L 29/7811; H01L 21/045; H01L 21/046; H01L 29/1608; H01L 29/66068

(57) ABSTRACT

A field effect transistor (FET) is proposed. The FET includes a transistor cell area in a silicon carbide (SiC) semiconductor body. An edge termination area surrounds the transistor cell area. A source contact is arranged over a first surface of the SiC semiconductor body. A drain contact is arranged on a second surface of the SiC semiconductor body. The FET further includes a drift region of a first conductivity type between the first surface and the second surface. Along a lateral direction, a net doping concentration in the drift region is larger in the transistor cell area than in the edge termination area.

### RELATED APPLICATION

This application claims priority to German Patent Application No. 102022124385.0, filed on Sep. 22, 2022, entitled “FIELD EFFECT TRANSISTOR COMPRISING EDGE TERMINATION AREA”, which is incorporated by reference herein in its entirety.

### TECHNICAL FIELD

The present disclosure is related to a field effect transistor (FET), in particular to a FET comprising an edge termination area in a silicon carbide (SiC) semiconductor body.

### BACKGROUND

Technology development of new generations of field effect transistor, such as, for example, SiC power semiconductor metal oxide semiconductor field effect transistors (MOSFETs), aims at improving electric device characteristics and reducing costs by shrinking device geometries. Although costs may be reduced by shrinking device geometries, a variety of tradeoffs and challenges have to be met when increasing device functionalities per unit area. For example, a trade-off between electric switching losses and voltage blocking capability requires design optimization.

Thus, there is a need for an improved field effect transistor.

### SUMMARY

An example of the present disclosure relates to a field effect transistor (FET). The FET includes a transistor cell area in a silicon carbide (SiC) semiconductor body. The FET further includes an edge termination area surrounding the transistor cell area. The FET further includes a source contact over a first surface of the SiC semiconductor body. The FET further includes a drain contact on a second surface of the SiC semiconductor body. The FET further includes a drift region of a first conductivity type between the first surface and the second surface. Along a lateral direction, a net doping concentration in the drift region may be larger in the transistor cell area than in the edge termination area.

Another example of the present disclosure relates to a method of manufacturing a field effect transistor (FET). The method includes forming a transistor cell area in a silicon carbide (SiC) semiconductor body. The method further includes forming an edge termination area surrounding the transistor cell area. The method further includes forming a source contact over a first surface of the SiC semiconductor body. The method further includes forming a drain contact on a second surface of the SiC semiconductor body. The method further includes forming a drift region of a first conductivity type between the first surface and the second surface. Along a lateral direction, a net doping concentration in the drift region may be larger in the transistor cell area than in the edge termination area.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of SiC semiconductor devices and together with the description serve to explain principles of the examples. Further examples are described in the following detailed description and the claims.

FIG. 1A is a partial cross-sectional view for illustrating an example of a FET including a transistor cell area and an edge termination area.

FIG. 1B is a schematic graph for illustrating a net doping concentration in a drift region of the FET of FIG. 1A that is larger in the transistor cell area than in the edge termination area.

FIGS. 2A to 2C are schematic graphs for illustrating exemplary vertical net doping concentration profiles in the transistor cell area and in the edge termination area.

FIG. 3 is a schematic graph for illustrating an exemplary lateral profile of the net doping concentration.

### DETAILED DESCRIPTION

In the following detailed description, reference is made to the accompanying drawings, which form a part hereof and in which are shown by way of illustrations specific examples of SiC FETs. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact may be a non-rectifying electrical junction.

Ranges given for physical dimensions include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of the present disclosure relates to a field effect transistor (FET). The FET may include a transistor cell area in a silicon carbide (SiC) semiconductor body. The FET may further include an edge termination area surrounding the transistor cell area. The FET may further include a source contact over a first surface of the SiC semiconductor body. The FET may further include a drain contact on a second surface of the SiC semiconductor body. The FET may further include a drift region of a first conductivity type between the first surface and the second surface. Along a lateral direction, a net doping concentration in the drift region may be larger in the transistor cell area than in the edge termination area.

The FET may be part of an integrated circuit or may be a discrete semiconductor device or a semiconductor module, for example. The FET may be or a may include an insulated gate field effect transistor (IGFET) such as a metal oxide semiconductor field effect transistor (MOSFET). The FET may be a vertical semiconductor device having a load current flow between the first surface and the second surface opposite to the first surface. The vertical power semiconductor device may be configured to conduct currents of more than 1 A, or more than 10 A, or more than 30 A, or more than 50 A, or more than 75 A, or even more than 100 A, and may be further configured to block voltages between load electrodes, such as, for example, between the drain contact and the source contact, in the range of several hundreds of up to several thousands of volts, such as, for example, 400 V, 650V, 1.2 kV, 1.7 kV, 3.3 kV, 4.5 kV, 5.5 kV, 6 kV, 6.5 kV, and/or 10 kV. The blocking voltage may correspond to a voltage class specified in a datasheet of the power semiconductor device, for example.

The FET may be based on a semiconductor body from a crystalline SiC material. For example, the semiconductor material may be 2H-SiC (SiC of the 2H polytype), 6H-SIC, 3C-SiC and/or 15R-SiC. According to an example, the semiconductor material may be silicon carbide of the 4H polytype (4H-SiC). The semiconductor body may consist of a semiconductor substrate or may include or consist of a semiconductor substrate having none, one or more than one SiC layers, such as, for example, epitaxially grown SiC layers, thereon.

The first surface may be a front surface or a top surface of the semiconductor body, and the second surface may be a back surface or a rear surface of the semiconductor body, for example. The semiconductor body may be attached to a lead frame via the second surface, for example. Over the first surface of the semiconductor body, bond pads may be arranged and bond wires may be bonded on the bond pads, for example.

For realizing a desired current carrying capacity, the FET may be designed by a plurality of parallel-connected transistor cells. The parallel-connected transistor cells may, for example, be transistor cells formed in the shape of a strip or a strip segment. The transistor cells can also have any other shape, such as, for example, circular, elliptical, polygonal such as hexagonal or octahedral. The transistor cells may be arranged in the transistor cell area of the semiconductor body. The transistor cell area may be an active area where a source region of the FET at the first surface and a drain region of the FET are arranged opposite to one another along the vertical direction. In the transistor cell area, a load current may enter or exit the semiconductor body of the FET, such as, for example, via contact plugs on the first surface of the semiconductor body. For example, the transistor cell or active area may be defined by an area where source contact plugs are placed over the first surface.

The edge termination area may include a termination structure. In a blocking mode or in a reverse biased mode of the FET, the blocking voltage between the transistor cell area and a field-free region laterally drops across the termination structure in the edge termination area. The termination structure may have a higher or a slightly lower voltage blocking capability than the transistor cell area. The termination structure may include a junction termination extension (JTE) with or without a variation of lateral doping (VLD), one or more laterally separated guard rings, or any combination thereof, for example.

The source contact and the drain contact may be part of a wiring area over the semiconductor body. The wiring area may include one or more than one, such as, for example, two, three, four or even more wiring levels. Each wiring level may be formed by a single one or a stack of conductive layers, such as, for example, metal layer(s). The wiring levels may be lithographically patterned, for example. Between stacked wiring levels, an interlayer dielectric structure may be arranged. Contact plug(s) or contact line(s) may be formed in openings in the interlayer dielectric structure to electrically connect parts, such as, for example, metal lines or contact areas, of different wiring levels to one another. The source contact may be formed by one or more elements of the wiring area over the first surface. Likewise, the drain electrode may be formed by one or more elements of the wiring area over the second surface.

The blocking voltage of the SiC FET may be adjusted by an impurity or doping concentration and/or a vertical extension of the drift region in the semiconductor body. A doping concentration of the drift region may gradually or in steps increase or decrease with increasing distance to the first surface at least in portions of its vertical extension. According to other examples, the impurity concentration in the drift region may be approximately uniform. A mean impurity concentration in the drift region may be between 5×10¹⁴ cm⁻³ and 1×10¹⁷ cm⁻³, for example in a range from 1×10¹⁵ cm⁻³ to 2×10¹⁶ cm⁻³. A vertical extent of the drift region may depend on voltage blocking requirements, such as, for example, a specified voltage class, of the FET. When operating the FET in voltage blocking mode, a space charge region may vertically extend partly or totally through the drift region depending on the blocking voltage applied to the FET. When operating the FET at or close to the specified maximum blocking voltage, the space charge region may reach or penetrate into a buffer region that may be configured to prevent the space charge region from further reaching to the drain contact at the second surface. The buffer region may have a higher doping concentration than the drift region. The vertical profile of doping concentration in the buffer region may enable an improvement of avalanche robustness and short circuit withstand capability. This may allow for improving reliability of the FET.

Along a lateral direction, a net doping concentration in the drift region may be larger in the transistor cell area than in the edge termination area. For example, at a vertical reference level in the drift region, the net doping concentration in a predominant part or in all of the transistor area may be larger than in the edge termination area. Apart from a transition region between the transistor cell area and the edge termination area, the net doping concentration at the vertical reference level may be constant in one or both of the edge termination area, or the transistor area. At the vertical reference level, the net doping concentration may also vary over part of the edge termination area, for example. Along the lateral direction, a minimum net doping concentration in the drift region may be larger in the transistor cell area than in the edge termination area, for example.

By reducing the net doping concentration in the edge termination area compared with the transistor cell area, the voltage blocking capability in the edge termination area may be increased. When reducing the net doping concentration in the edge termination area based on ion implantation, such as, for example, ion implantation of light ions for partially compensating the drift region doping based on defect complexes region, the ion implantation of the light ions may also result in a reduction of the mobility of the electrons in the edge termination area, such as, for example, in the case of irradiation with protons. This may allow for reducing avalanche multiplication in the edge termination area and thus contributes to the increase of the breakdown field strength. As an additional benefit, the width or chip area consumption of the edge termination area may be reduced. Since the partial compensation of first conductivity type dopants in the drift region doping may result in dE/dx (electric field gradient) becoming smaller, for a given reverse voltage or blocking voltage, the electric field strength may also be reduced, and thus also the stress on the hard or soft encapsulation may be reduced.

The examples and features described above and below may be combined.

For example, the doping concentration of the first conductivity type in the edge termination area may be partially compensated. When assuming that the first conductivity is n-type, in this case, a number of acceptors may compensate a corresponding number of donors so that no free carriers of either type result from this compensation. Since the donors outnumber the acceptors for net n-type doping, (only, for example) the excess donors will result in free carriers.

For example, a maximum partial compensation of the doping concentration of the first conductivity type along the lateral direction in the edge termination area may range from 10% to 90%, or from 20% to 80%, or from 30% to 70%.

For example, the first conductivity type may be n-type, and partial compensation of the n-type doping in the edge termination area may be based on defect complexes.

For example the defect complexes may include carbon-vacancy complexes.

For example, the FET may further comprise a buffer region of the first conductivity type arranged between the drift region and the second surface. A maximum doping concentration in the buffer region may be larger than in the drift region.

For example, a profile of a vertical net doping concentration through the drift region and through at least part of the buffer region may have a single valley in the edge termination area. The single valley may be absent in the transistor cell area or may be absent in at least a predominant part of the transistor cell area, for example.

For example, the single valley may be located in the drift region. This may allow for adjusting the net doping in an area where high electric field strengths occur during blocking voltage operation. For example, the single valley may have a vertical distance to the termination structure that may be large enough so that a vertical decrease of the net doping concentration toward the single valley starts below the termination structure, i.e. does not overlap a vertical doping profile of the termination structure.

For example, the single valley may be located in the buffer region.

For example, a profile of a vertical net doping concentration through the drift region and through at least part of the buffer region may have a plurality of valleys. This may allow for more flexibility in adjusting the net doping concentration profile in the edge termination area and may thus improve the trade-off between electric switching losses and voltage blocking capability.

For example, at least one of the plurality of valleys may be located in the drift region and at least another one of the plurality of valleys may be located in the buffer region.

Details with respect to structure, or function, or technical benefit of features described above with respect to a FET likewise apply to the exemplary methods described herein. Processing the semiconductor body may comprise one or more optional additional features corresponding to one or more aspects mentioned in connection with the proposed concept or one or more examples described above or below.

An example of the present disclosure relates to a method for manufacturing a field effect transistor (FET). The method may comprise forming a transistor cell area in a silicon carbide (SiC) semiconductor body. The method may further comprise forming an edge termination area surrounding the transistor cell area. The method may further comprise forming a source contact over a first surface of the SiC semiconductor. The method may further comprise forming a drain contact on a second surface of the SiC semiconductor body. The method may further comprise forming a drift region of a first conductivity type between the first surface and the second surface. Along a lateral direction, a net doping concentration in the drift region may be larger in the transistor cell area than in the edge termination area.

For example, the net doping concentration may be reduced in the edge termination area by partial compensation based on defect complexes. For example, the defect complexes may include carbon-vacancy complexes.

For example, forming the defect complexes may include introducing light ions through the first surface into the SiC semiconductor body by ion implantation. The light ions may include at least one of helium ions, protons, deuterium, Lithium. For example, the light ions may be based on non-doping elements, i.e. the implanted light ions may not be electrically activated by annealing for acting as shallow donor or shallow acceptor. The light ions may form part of a defect complex, such as, for example, a complex including vacancies. The defect complex may cause partial compensation of doping in the drift region and/or buffer region, for example. For example, the light ions may be based on elements having an ordinal or atomic number smaller than 4.

For example, the light ions may be implanted at different ion implantation energies and/or implantation angles. This may allow for more flexibility in adjusting the net doping concentration profile in the edge termination area and may thus improve the trade-off between electric switching losses and voltage blocking capability requires.

For example, the SiC semiconductor body may be thermally processed, after implanting the light ions, by a temperature budget in a temperature range from 250° C. to 400° C. for a time period ranging from 30 minutes to 4 hours. This may counteract instabilities during device operation by a stabilizing thermal processing. The light ions may be introduced into semiconductor body after forming the drain contact or a part thereof on the second surface, for example.

For example, the light ions may be implanted after forming a passivation layer, such as, for example, an imide layer, over a wiring area at the first surface.

For example, the method may further comprise curing the passivation layer by the thermal budget. The thermal budget used for curing the imide may thus simultaneously be used for the stabilizing thermal processing of the implanted light ions.

For example, the light ions may be introduced into the SiC semiconductor body in the edge termination area after forming the drift region or prior to forming a gate trench or a planar gate or after forming a termination structure in the edge termination area. The SiC semiconductor body may be thermally processed, after implanting the light ions, by a temperature budget in a temperature range from 800° C. to 1900° C.

The ion implantation of light ions for reducing the net doping concentration in the edge termination area by partially compensating the drift region doping may be undesired in the transistor cell area for avoiding any negative impact on the electric characteristics in the transistor cell area. Therefore, a mask may avoid introduction of the light ions into the transistor cell area. for example, a resist mask layer or a metal layer or a stencil mask may be used. In particular, implantation after deposition and patterning of wiring levels, such as, for example, metal layers, over the first surface may be used for avoiding implantation of the light ions into the transistor cell area.

More details and aspects are mentioned in connection with the examples described above or below. Processing a SiC semiconductor wafer may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, such as, for example, by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

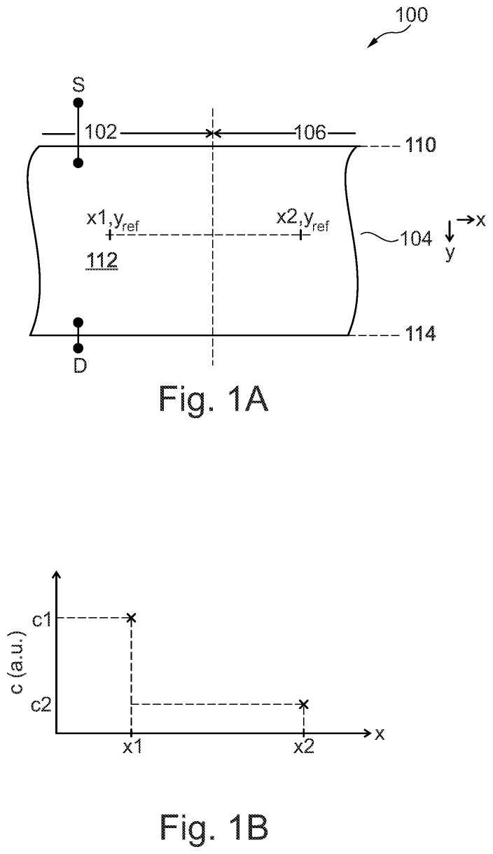

FIG. 1A schematically and exemplarily shows a partial cross-sectional view of a FET 100. The FET may be a trench gate or planar gate FET, for example. The FET 100 includes a transistor cell area 102 in a silicon carbide (SiC) semiconductor body 104. An edge termination area 106 laterally surrounds the transistor cell area 102. The FET 100 further includes a source contact S over a first surface 110 of the SiC semiconductor body 104, and a drain contact D on a second surface 114 of the SiC semiconductor body 104. The FET 100 further includes a drift region 112 of a first conductivity type between the first surface 110 and the second surface 114. Along a lateral direction x, such as, for example, at a same vertical level yref, a net doping concentration c in the drift region 112 may be larger in the transistor cell area 102, such as, for example, at a lateral position x1, than in the edge termination area 106, such as, for example, at a lateral position x2.

FIG. 1B is a schematic graph for illustrating a net doping concentration c1 in the drift region 112 at the lateral position x1 in the transistor cell area 102 that may be larger than a net doping concentration c2 in the drift region 112 at the lateral position x2 in the edge termination area 106.

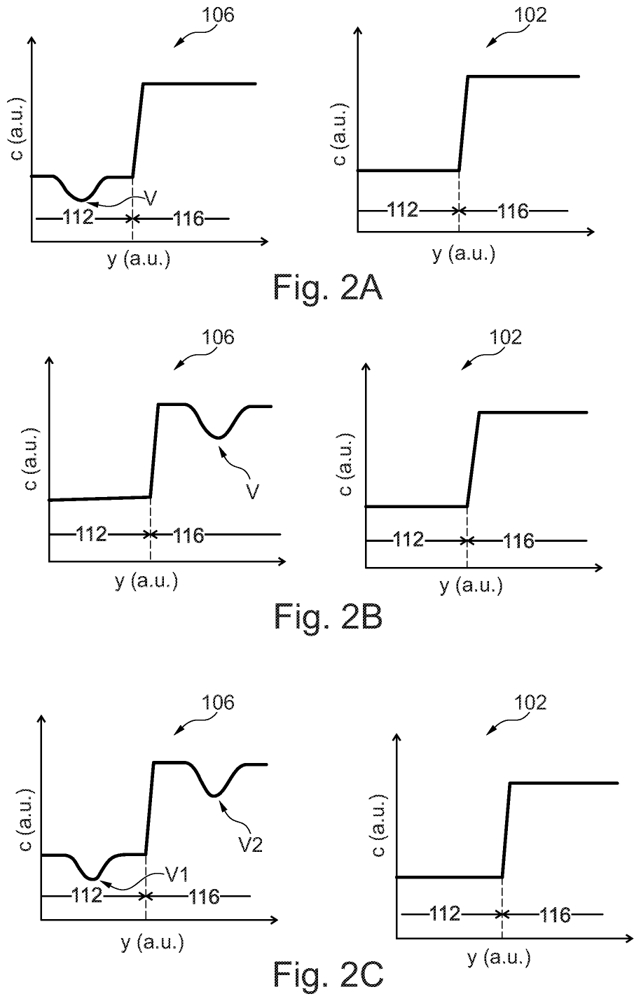

The schematic graphs of FIGS. 2A to 2C illustrate exemplary net doping concentrations c versus the vertical direction y through a part of the drift region 112 and through a part of a buffer region 116 arranged between the drift region 112 and the second surface 114. The left graph in each of FIGS. 2A to 2C refers to the vertical net doping concentration c at a lateral position in the edge termination area 106, such as, for example, lateral position x2 as illustrated in FIG. 1A.

The right graph in each of FIGS. 2A to 2C refers to the vertical net doping concentration at a lateral position in the transistor cell area 102, such as, for example, lateral position x1 as illustrated in FIG. 1A. The net doping concentration c may be determined by any appropriate characterization technique, such as, for example, spreading resistance profiling (SRP).

Referring to FIG. 2A, the profile of a vertical net doping concentration c through the drift region 112 and through at least part of the buffer region 116 has a single valley V located in the drift region 112 in the edge termination area 106. The single valley may be absent in the transistor cell area 102. To optimize the effect of this reduction of the drift zone doping, the distance between the pn-junction and the resulting minimum should be relatively close to the pn-junction; i.e. the vertical distance between the pn-junction and this minimum should be for example less than 5 micrometer or even better less than 3 micrometer or even better less than 2 micrometer.

Referring to FIG. 2B, the profile of a vertical net doping concentration c through the drift region 112 and through at least part of the buffer region 116 has a single valley V located in the buffer region 116 in the edge termination area 106. The single valley may be absent in the transistor cell area 102.

The profile of a vertical net doping concentration through the drift region 112 and through at least part of the buffer region 116 may also have a plurality of valleys as is schematically and exemplarily illustrated in FIG. 2C. Referring to FIG. 2C, the profile of a vertical net doping concentration c through the drift region 112 and through at least part of the buffer region 116 has a first valley V1 located in drift region 112 and a second valley V2 located in the buffer region 116 of the edge termination area 106. The valleys are absent in the transistor cell area 102. Several valleys in the drift region are possible, too.

The number of valleys in the drift region 112 and in the buffer region 116 may be appropriately chosen for improving the trade-off between electric switching losses and voltage blocking capability, for example.

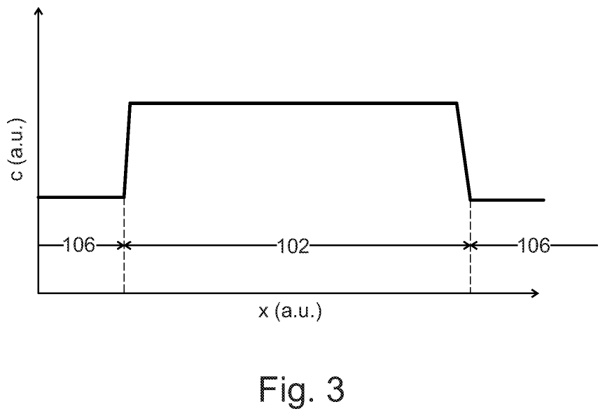

The schematic graph of FIG. 3 illustrates an exemplary net doping concentration c versus the lateral direction x through a part of the edge termination area 106 and through the transistor cell area 102. Apart from a transition region between the transistor cell area 102 and the edge termination area 106, the net doping concentration c at a vertical reference level may be constant in one or both of the edge termination area 106, or the transistor cell area 102. At the vertical reference level, such as, for example, vertical reference level yref in FIG. 1A, the net doping concentration c may be constant along the lateral direction x in the transistor cell area 102 and has a smaller and constant value in the edge termination area 106.

The description and drawings merely illustrate the principles of the disclosure. Furthermore, all examples recited herein are principally intended expressly to be only for illustrative purposes to aid the reader in understanding the principles of the disclosure and the concepts contributed furthering the art. All statements herein reciting principles, aspects, and examples of the disclosure, as well as specific examples thereof, are intended to encompass equivalents thereof.

The aspects and features mentioned and described together with one or more of the previously detailed examples and figures, may as well be combined with one or more of the other examples in order to replace a like feature of the other example or in order to additionally introduce the feature to the other example.

1. A field effect transistor (FET), comprising:
a transistor cell area in a silicon carbide (SiC) semiconductor body;
an edge termination area surrounding the transistor cell area;
a source contact over a first surface of the SiC semiconductor body;
a drain contact over a second surface of the SiC semiconductor body; and
a drift region of a first conductivity type between the first surface and the second surface, wherein a first doping concentration in a first portion of the drift region in the transistor cell area is larger than a second doping concentration in a second portion of the drift region in the edge termination area.

2. The FET of claim 1, wherein the second doping concentration in the edge termination area is partially compensated.

3. The FET of claim 2, wherein a maximum partial compensation of the second doping concentration in the edge termination area is within a range from 10% to 90%.

4. The FET of claim 2, wherein the first conductivity type is n-type, and partial compensation of n-type doping in the edge termination area is based on one or more defect complexes.

5. The FET of claim 4, wherein the one or more defect complexes comprise one or more carbon-vacancy complexes.

6. The FET of claim 1, further comprising a buffer region of the first conductivity type arranged between the drift region and the second surface, wherein a first maximum doping concentration in the buffer region is larger than a second maximum doping concentration in the drift region.

7. The FET of claim 6, wherein a profile of a vertical net doping concentration through the drift region and through at least part of the buffer region has a single valley in the edge termination area.

8. The FET of claim 7, wherein the single valley is located in the drift region.

9. The FET of claim 7, wherein the single valley is located in the buffer region.

10. The FET of claim 6, wherein a profile of a vertical net doping concentration through at least part of the drift region and through at least part of the buffer region has a plurality of valleys.

11. The FET of claim 10, wherein at least one of the plurality of valleys is located in the drift region and at least another one of the plurality of valleys is located in the buffer region.

12. A method of manufacturing a field effect transistor (FET), the method comprising:
forming a transistor cell area in a silicon carbide (SiC) semiconductor body;
forming an edge termination area surrounding the transistor cell area;
forming a source contact over a first surface of the SiC semiconductor body;
forming a drain contact on a second surface of the SiC semiconductor body;
forming a drift region of a first conductivity type between the first surface and the second surface, wherein a first doping concentration in a first portion of the drift region in the transistor cell area is larger than a second doping concentration in a second portion of the drift region in the edge termination area.

13. The method of claim 12, further comprising forming one or more defect complexes by implanting light ions through the first surface into the SiC semiconductor body, wherein the light ions comprise at least one of one or more helium ions, one or more protons, deuterium, or Lithium.

14. The method of claim 13, wherein the light ions are implanted at different ion implantation energies.

15. The method of claim 13, wherein the SiC semiconductor body is thermally processed, after implanting the light ions, by a temperature budget in a temperature range from 250° C. to 400° C. for a time period ranging from 30 minutes to 4 hours.

16. The method of claim 15, wherein the light ions are implanted after forming a passivation layer over a wiring area at the first surface.

17. The method of claim 16, further comprising curing the passivation layer by the temperature budget.

18. The method of claim 13, wherein the light ions are implanted into the SiC semiconductor body in the edge termination area at least one of:
after forming the drift region;
prior to forming at least one of a gate trench or a planar gate; or
after forming a termination structure in the edge termination area.

19. The method of claim 18, wherein the SiC semiconductor body is thermally processed, after implanting the light ions, by a temperature budget in a temperature range from 800° C. to 1900° C.

20. A field effect transistor (FET), comprising:
a transistor cell area in a silicon carbide (SiC) semiconductor body;
an edge termination area surrounding the transistor cell area;
a source contact over a first surface of the SiC semiconductor body;
a drain contact over a second surface of the SiC semiconductor body; and
a drift region between the first surface and the second surface, wherein a first doping concentration in a first portion of the drift region in the transistor cell area is different than a second doping concentration in a second portion of the drift region in the edge termination area.
